(19) United States
(12) Patent Application Publication
(10) Pub. No.: US 2008/0169847 A1
(43) Pub. Date: Jul. 17, 2008

(54) DRIVER AND DRIVER/RECEIVER SYSTEM

(76) Inventor: Kyoichi TAKENAKA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/972,239

(22) Filed: Jan. 10, 2008

(30) Foreign Application Priority Data
Jan. 11, 2007 (JP) 2007-003541

(51) Int. Cl. H03B 1/00

(52) U.S. Cl. 327/108

(57) ABSTRACT

A driver includes an output circuit which converts an input signal to a predetermined output waveform and outputs the predetermined waveform to first and second output terminals, a first output resistor having one end connected to the first output terminal, a second output resistor having one end connected to the second output terminal, an output resistor switch element having one end connected to the other end of the first output resistor, and having the other end connected to the other end of the second output resistor, and a 2-input-2-output amplifier which receives first and second input voltages corresponding to voltages at both ends of the output resistor switch element, and outputs voltages, which are produced by amplifying voltage differences between a reference voltage and the first and second input voltages, a high impedance state being set between both ends of the output resistor switch element.

### CROSS-REFERENCE TO RELATED APPLICATIONS

This application is based upon and claims the benefit of priority from prior Japanese Patent Application No. 2007-003541, filed Jan. 11, 2007, the entire contents of which are incorporated herein by reference.

### BACKGROUND OF THE INVENTION

1. Field of the Invention

The present invention relates to a driver and a driver/receiver system, and the invention is applied, for example, to a driver which adopts a variable output impedance LVDS (Low Voltage Differential Signaling) method.

2. Description of the Related Art

Conventionally, there is known a driver which adopts, for example, a variable output impedance LVDS (Low Voltage Differential Signaling) method (hereinafter referred to as “LVDS driver”) (see, for instance, Jpn. Pat. Appln. KOKAI Publications No. H9-214314 and No. 2006-60320). There is an LVDS driver which includes a switch for turning on/off the conduction path between output resistors which are connected to two output terminals.

In the structure of the conventional LVDS, however, there is a tendency that the circuit area increases, which is disadvantageous for microfabrication.

The reason for this is as follows. In a case where a MOS transistor (MOSFET), which is fabricated by an ordinary CMOS fabrication process, is used as the above-described switch, it is necessary to make an ON resistance (Rsw) of the switch (MOSFET) sufficiently lower than an output resistance (e.g. about 50Ω) of the LVDS driver. As a result, the gate width (W) of the switch (MOSFET) considerably increases, and the area of occupation of the switch (MOSFET) greatly increases. The great increase in occupation area of the switch (MOSFET) leads to an increase in area of the entirety of the driver, and this is disadvantageous in terms of manufacturing cost.

In addition, with the great increase in occupation area of the switch (MOSFET), a parasitic capacitance between the gate and drain of the switch and a parasitic capacitance between the gate and source of the switch also increase, and power supply noise may easily be mixed in.

### BRIEF SUMMARY OF THE INVENTION

According to an aspect of the present invention, there is provided a driver comprising: an output circuit which converts an input signal to a predetermined output waveform and outputs the predetermined waveform to first and second output terminals; a first output resistor having one end connected to the first output terminal; a second output resistor having one end connected to the second output terminal; an output resistor switch element having one end connected to the other end of the first output resistor, and having the other end connected to the other end of the second output resistor; and a 2-input-2-output amplifier which receives first and second input voltages corresponding to voltages at both ends of the output resistor switch element, and outputs voltages, which are produced by amplifying voltage differences between a reference voltage and the first and second input voltages, once again to both ends of the output resistor switch element as first and second output voltages, a high impedance state being set between both ends of the output resistor switch element when a stop signal is input to the 2-input-2-output amplifier.

According to another aspect of the present invention, there is provided a driver/receiver system comprising: a driver, the driver including: an output circuit which converts an input signal to a predetermined output waveform and outputs the predetermined waveform to first and second output terminals; a first output resistor having one end connected to the first output terminal; a second output resistor having one end connected to the second output terminal; an output resistor switch element having one end connected to the other end of the first output resistor, and having the other end connected to the other end of the second output resistor; and a 2-input-2-output amplifier which receives first and second input voltages corresponding to voltages at both ends of the output resistor switch element, and outputs voltages, which are produced by amplifying voltage differences between a reference voltage and the first and second input voltages, once again to both ends of the output resistor switch element as first and second output voltages, a high impedance state being set between both ends of the output resistor switch element when a stop signal is input to the 2-input-2-output amplifier; and a receiver which receives output signals of the driver, which are output from the first and second output terminals.

### BRIEF DESCRIPTION OF THE SEVERAL VIEWS OF THE DRAWING

FIG. 1 shows a driver/receiver system according to a first embodiment of the present invention;

FIG. 2 is a block diagram showing an LVDS driver (driver) according to the first embodiment;

FIG. 3 is a circuit diagram showing an LVDS output circuit (output circuit) in FIG. 1;

FIG. 4 shows an ON resistance between the drain and source in the ON state of the switch in FIG. 1;

FIG. 5 shows a structure in which an output resistance switch element according to the first embodiment is composed of a PMOS transistor;

FIG. 6 shows a structure in which the output resistance switch element according to the first embodiment is composed of an NMOS transistor;

FIG. 7 shows a structure in which the output resistance switch element according to the first embodiment is composed of a CMOS switch;

FIG. 8 is a circuit diagram showing an example of the structure of a 2-input-2-output amplifier according to the present embodiment;

FIG. 9 shows a case in which a control signal (Φ, −Φ) is input to a gate of a switch transistor of the output circuit according to the first embodiment;

FIG. 10 shows a switch control signal and an output waveform of the driver according to the first embodiment;

FIG. 11 is a circuit diagram showing an example of the structure in which a plurality of amplifiers in the 2-input-2-output amplifier according to the first embodiment are integrated into one amplifier;

FIG. 12 is a circuit diagram showing an example of the structure of a 2-input-2-output amplifier according to the present embodiment;

FIG. 13 is a small signal equivalent circuit of the 2-input-2-output amplifier according to the present embodiment, which is shown in FIG. 12;

FIG. 14 is an equivalent circuit diagram showing a further simplified circuit of the small signal equivalent circuit shown in FIG. 13;

FIG. 15 is a block diagram showing a driver according to a second embodiment of the present invention;

FIG. 16 is a circuit diagram showing an example of the structure of an average voltage generating circuit according to the second embodiment;

FIG. 17 is a circuit diagram showing another example of the structure of the average voltage generating circuit according to the second embodiment;

FIG. 18 is a circuit diagram showing still another example of the structure of the average voltage generating circuit according to the second embodiment;

FIG. 19 shows an example of the structure of a 2-output amplifier according to the second embodiment;

FIG. 20 shows another example of the structure of the 2-output amplifier according to the second embodiment;

FIG. 21 shows still another example of the structure of the 2-output amplifier according to the second embodiment;

FIG. 22 is a block diagram showing a driver according to a third embodiment of the present invention;

FIG. 23 is a circuit diagram showing a driver according to a comparative example;

FIG. 24 is an equivalent circuit diagram for explaining an output impedance, as viewed from an output terminal in the comparative example;

FIG. 25 shows a buffer amplifier according to the comparative example, in a case where an operational amplifier of a two-stage amplifier structure is applied to the buffer amplifier;

FIG. 26 shows a simplified model as an example of the structure of the buffer amplifier according to the comparative example;

FIG. 27 is a small signal equivalent circuit diagram of an operational amplifier according to the comparative example, in which a first-stage amplifier and a transistor are represented by a modeled voltage control current source and an output resistor; and

FIG. 28 is a small signal equivalent circuit diagram in a case where a buffer amplifier according to the comparative example shown in FIG. 24 is replaced with a model as shown in FIG. 27.

### DETAILED DESCRIPTION OF THE INVENTION

Embodiments of the present invention will now be described with the accompanying drawings. In the description below, common parts are denoted by like reference numerals throughout the drawings.

### Embodiment

### An Example of Basic Structure

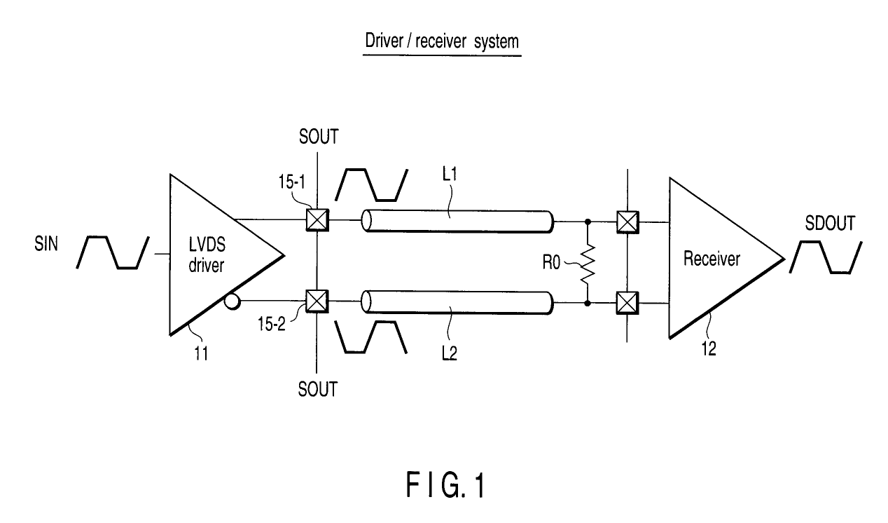

An example of the basic structure of a driver according to an embodiment of the present invention is described with reference to FIG. 1 to FIG. 9. In this embodiment, a driver, which adopts a variable output impedance small amplitude differential signaling (LVDS: Low Voltage Differential Signaling) method, is exemplified.

### <1. Driver/Receiver System>

To begin with, a driver/receiver system, which includes the driver according to the present embodiment, is described with reference to FIG. 1. FIG. 1 shows a driver/receiver system according to the embodiment.

As shown in FIG. 1, the driver/receiver according to the embodiment includes an LVDS driver (driver circuit) 11 and a receiver 12, which are connected by transmission lines L1 and L2.

As will be described later, the LVDS driver 11 is configured to amplify an input signal SIN by a small amplitude differential signaling method (LVDS) and to output a predetermined driver output signal SOUT to the receiver 12 from output terminals 15-1 and 15-2. In this manner, by using the small amplitude differential signaling method (LVDS), the LVDS driver 11 can perform differential transmission with a small signal amplitude. Therefore, the amount of occurring noise can be reduced, and the power consumption can be decreased.

The receiver 12 is configured to receive the driver output signal SOUT that is input via the transmission lines L1 and L2.

Normally, the LVDS driver 11 includes a terminal end resistor R0 which has one end and the other end connected between differential output terminals. For example, the resistance value of the terminal end resistor R0 is about 100Ω.

The LVDS driver 11 prevents reflection of the output signal SOUT by matching the transmission line impedance of the transmission line L1, L2 and the impedance of the terminal end resistor R0 at the input section of the receiver 12.

However, in the case where the differential output terminals (e.g. output pins) 15-1 and 15-2 of the LVDS driver 11 are shared with other circuits, it is necessary to set the output resistance between the differential output terminals 15-1 and 15-2 in the open state.

For this purpose, at first, the LVDS driver 11 needs to be configured such that the ON state (conductive state) can be set between the differential output terminals 15-1 and 15-2 and the OFF state (non-conductive state) can be set between the differential output terminals 15-1 and 15-2.

Second, the LVDS driver 11 needs to be configured to realize, with a small increase in device area, switching between the two states, i.e. the ON state and OFF state of connection between the differential output terminals 15-1 and 15-2.

Third, the LVDS driver 11 needs to be configured to reduce, regardless of fabrication processes and operational environments, a variation in output resistance value due to the switching between the two states, i.e. the ON state and OFF state of conduction between the differential output terminals 15-1 and 15-2.

### <2. Example of Structure of LVDS Driver 11>

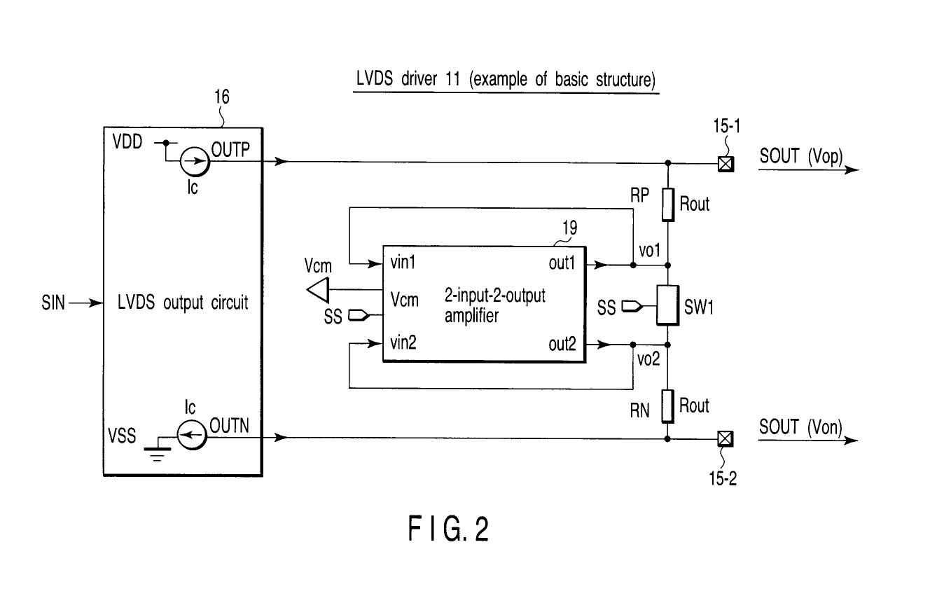

Next, referring to FIG. 2, a description is given of an example of the structure of the LVDS driver 11 according to the embodiment. As shown in FIG. 2, the LVDS driver 11 includes an LVDS output circuit 16, output resistors RP and RN, an output resistor switch element SW1, and a 2-input-2-output amplifier 19 to which a stop signal SS is input.

The LVDS output circuit 16 is configured to convert a driver input signal SIN, which is input, to a predetermined output waveform signal by the small amplitude differential signaling method (LVDS) and to output the predetermined output waveform signal.

The output resistor RP is an output resistor having one end connected to the output terminal (first output terminal) 15-1 and the other end connected to one end of a current path of the output resistor switch element SW1.

The output resistor RN is an output resistor having one end connected to the output terminal (second output terminal) 15-2 and the other end connected to the other end of the current path of the output resistor switch element SW1.

The output resistor switch element SW1 has the current path with the one end and the other end connected to the other ends of the output resistors RP and RN, respectively.

The 2-input-2-output amplifier 19 is configured to receive a first input voltage Vin1 and a second input voltage Vin2, which correspond to voltages at both ends of the output resistor switch element SW1, and to output first and second output voltages Vo1 and Vo2, which are obtained by amplifying voltage differences between the first and second input voltages Vin1 and Vin2 and a reference voltage Vcm, once again to both ends of the output resistor switch element SW1.

In addition, the 2-input-2-output amplifier 19 is configured such that if the stop signal SS is input to the 2-input-2-output amplifier 19, a high impedance state is set between both ends of the output resistor switch element SW1. The output resistor switch element SW1 is configured such that if the stop signal SS is input to the gate of the element SW1, a high impedance state is set between both ends of the output resistor switch element SW1. Thus, if the stop signal SS is input to the 2-input-2-output amplifier 19, an open state is set between the output terminals (out1, out2) of the 2-input-2-output amplifier 19.

### <3. Example of Structure of LVDS Output Circuit 16>

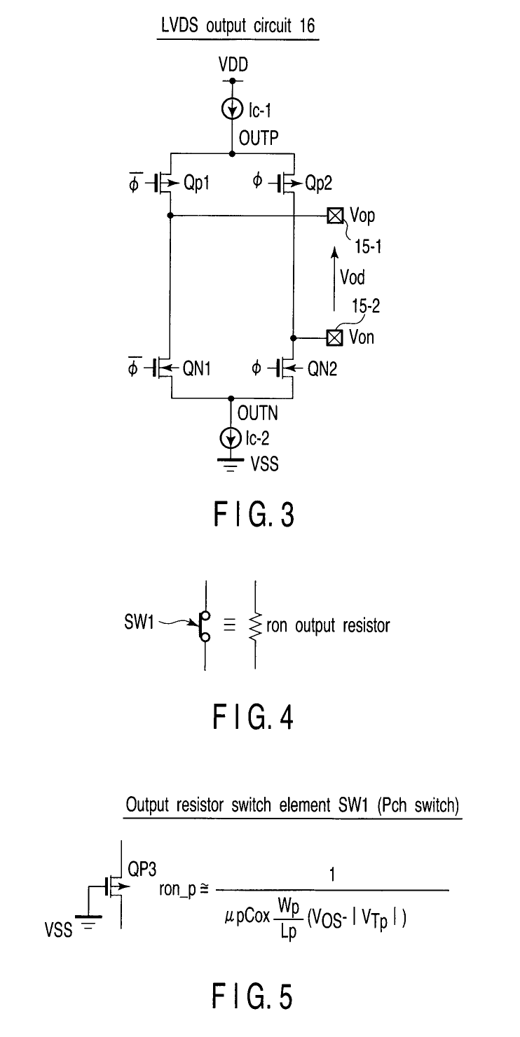

Next, an example of the structure of the LVDS output circuit 16 relating to the present embodiment is described with reference to FIG. 3. As shown in FIG. 3, the LVDS output circuit 16 according to this example comprises current sources Ic-1 and Ic-2, PMOS transistors QP1 and QP2, and NMOS transistors QN1 and QN2. The voltage states of control signals Φ and −Φ are opposite to each other. For example, in the logical voltage states shown in FIG. 3, the MOS transistors QP2 and QN1 are turned on, and the MOS transistors QP1 and QN2 are turned off.

An input of the current source Ic-1 is connected to a reference power supply VDD, and an output of the current source Ic-1 is connected to the sources of the PMOS transistors QP1 and QP2.

An input of the current source Ic-2 is connected to a ground power supply VSS, and an output of the current source Ic-2 is connected to the sources of the NMOS transistors QN1 and QN2.

The drain of the PMOS transistor QP1 is connected to the output terminal 15-1, and the control signal −Φ is input to the gate of the PMOS transistor QP1. The drain of the PMOS transistor QP2 is connected to the output terminal 15-2, and the control signal Φ is input to the gate of the PMOS transistor QP2.

The drain of the NMOS transistor QN1 is connected to the output terminal 15-1, and the control signal −Φ is input to the gate of the NMOS transistor QN1. The drain of the NMOS transistor QN2 is connected to the output terminal 15-2, and the control signal Φ is input to the gate of the NMOS transistor QN2.

Accordingly, as regards the MOS switches QP1, QP2, QN1 and QN2, when the control signal Φ is at the level of the reference power supply VDD, the MOS switches QP1 and QN2 are turned on and the MOS switches QN1 and QP2 are turned off. On the other hand, when the control signal φ is at the level of the ground power supply VSS, the MOS switches QP1 and QN2 are turned off and the MOS switches QP2 and QN1 are turned on.

As described above, the LVDS output circuit 16 of this embodiment is different from an LVDS differential amplifier circuit 116 according to a comparative example (to be described later) in that the LVDS output circuit 16 does not include a buffer amplifier 117 which functions as an amplifier unit.

### <4. Example of Structure of Switch Element SW1>

Next, an example of the structure of the above-described switch element SW1 according to the present embodiment is described with reference to FIG. 4 to FIG. 7. As shown in FIG. 4, in the description below, it is assumed that the resistance value of an ON resistance between the drain and source in the ON state of the output resistor switch element SW1 is a resistance value ron.

<4-1. Example in which the Switch Element SW1 is Composed of a PMOS Transistor (Pch Switch)>

In an example shown in FIG. 5, the output resistor switch element SW1 is composed of a PMOS transistor QP3. As shown in FIG. 5, the source of the PMOS transistor QP3 is connected to the output terminal 15-1 via the output resistor RP, the drain of the PMOS transistor QP3 is connected to the output terminal 15-2 via the output transistor RN, and the gate of the PMOS transistor QP3 is connected to the ground power supply VSS.

<4-2. Example in which the Switch Element SW1 is Composed of an NMOS Transistor (Nch Switch)>

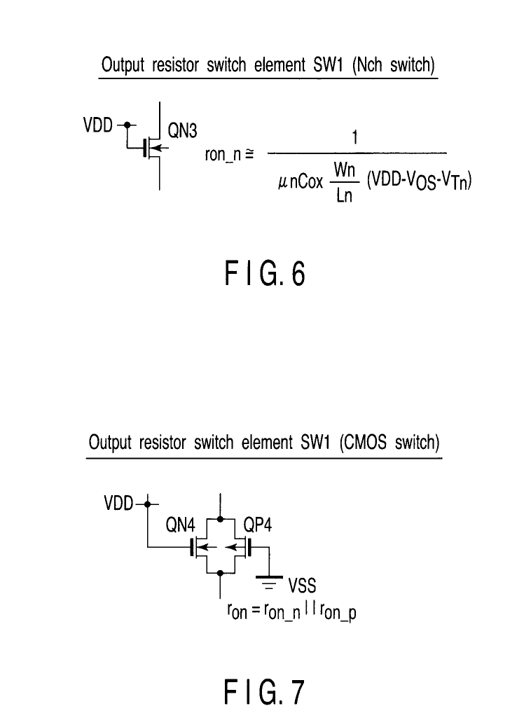

In an example shown in FIG. 6, the output resistor switch element SW1 is composed of an NMOS transistor QN3. As shown in FIG. 6, the source of the NMOS transistor QN3 is connected to the output terminal 15-2 via the output resistor RN, the drain of the NMOS transistor QN3 is connected to the output terminal 15-1 via the output transistor RP, and the gate of the NMOS transistor QN3 is connected to the reference power supply VDD.

<4-3. Example in which the Switch Element SW1 is Composed of a CMOS Switch>

In an example shown in FIG. 7, the output resistor switch element SW1 is composed of a CMOS switch. As shown in FIG. 7, the CMOS switch comprises MOS transistors QP4 and QN4.

The source of the PMOS transistor QP4 is connected to the output terminal 15-1 via the output resistor RP, the drain of the PMOS transistor QP4 is connected to the output terminal 15-2 via the output transistor RN, and the gate of the PMOS transistor QP4 is connected to the ground power supply VSS. The source of the NMOS transistor QN4 is connected to the drain of the PMOS transistor QP4, the drain of the NMOS transistor QN4 is connected to the source of the PMOS transistor QP4, and the gate of the NMOS transistor QN4 is connected to the reference power supply VDD.

The resistance values ron of the ON resistances, which are described in the above <4-1> to <4-3>, are expressed by:

$${r}_{on\_n} = \frac{1}{{μ}_{n} {C}_{OX} \frac{{W}_{n}}{{L}_{n}} ( {V}_{DD} - {V}_{OS} - {V}_{TN} )} \\ {r}_{on\_p} = \frac{1}{{μ}_{p} {C}_{OX} \frac{{W}_{p}}{{L}_{p}} ( {V}_{OS} - \vert {V}_{{T}_{p}} \vert )} \\ {r}_{on} = ( {r}_{on\_n} \vert \vert {r}_{on\_p} ) \qquad equation ( 1 )$$

where V_{TN} and V_{TP} are threshold values of the NMOS transistors QN3 and QP3, and μ_{N} and μ_{P} are the mobility of electrons and the mobility of holes, respectively. These values of the threshold voltages and mobilities are variable depending on temperatures. Cox is the unit area capacity of the oxide film, and W and L are the channel width and channel length of the transistor, respectively.

In the above equation (1), the mobility μ_{N}, μ_{P}, the unit area capacity Cox of the oxide film, and the threshold voltage V_{TN}, V_{TP} are inherent values of the device. The minimum value of the channel length L is restricted by the precision in microfabrication. Normally, when the MOSFET switch is designed, the minimum value of the channel length L is set at a minimum value that is set by design rules, in order to decrease the ON resistance value. Besides, the reference power supply VDD and offset voltage Vos are normally set by circuit specifications.

Accordingly, in the circuit design stage, the parameter, which has a degree of freedom in order to determine the ON resistance of the MOSFET switch, is only the channel width W. Thus, the channel width W needs to be increased in order to decrease the ON resistance.

When one of the PchFET switch QP3, NchFET switch QN3 and CMOS switch, which are shown in the above <4-1> to <4-3>, is to be chosen as the output resistor switch element SW1, it is preferable, in terms of area cost, to give consideration to the mobilities of electrons and holes and the voltage values of the reference power supply VDD and offset voltage Vos that are determined by specifications, and to choose the switch which minimizes the area even with the same resistance value.

No matter which of the structures of the above <4-1> to <4-3> is chosen, the resistance value ron of the ON resistance of the output resistor switch element SW1 has the following relationship expressed by formula (2):

$${r}_{on} ∝ \frac{1}{W} \qquad ( 2 )$$

As has been described above, in order to reduce the ON resistance value ron, the channel width W has to be increased.

### <5. Example of Structure of 2-Input-2-Output Amplifier 19>

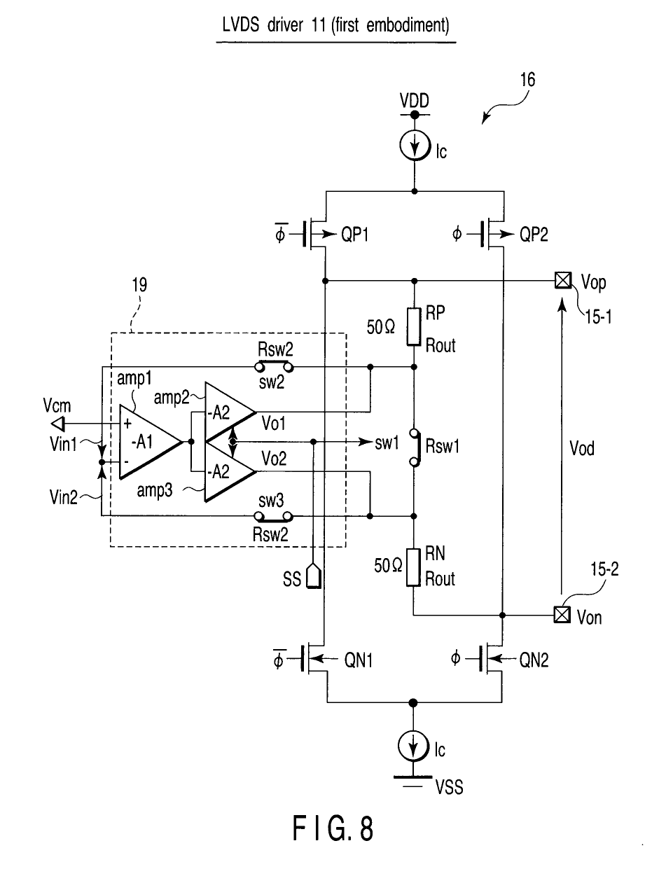

Next, an example of the structure of the 2-input-2-output amplifier 19 according to the present embodiment is described with reference to FIG. 8. As shown in FIG. 8, the 2-input-2-output amplifier 19 according to this example includes switch elements SW2 and SW3 and amplifiers amp1 to amp3.

One end of a current path of the switch element SW2 is connected to the said other end of the output resistor RP, and the other end of the current path is connected to the first input (first input voltage Vin1) of the amplifier 19. One end of a current path of the switch element SW3 is connected to the said other end of the output resistor RN, and the other end of the current path is connected to the second input (second input voltage Vin2) of the amplifier 19.

The amplifier amp1 is configured such that the reference voltage Vcm is input to a first input terminal of the amplifier amp1 and the first input voltage Vin1 and second input voltage Vin2 of the amplifier 19 are input to a second input terminal of the amplifier amp1, and outputs corresponding to differences between the reference voltage Vcm and the first input voltage Vin1 and second input voltage Vin2 are delivered to the amplifiers amp2 and amp3. In addition, the amplifier amp1 has a gain −A1.

The output voltage of the amplifier amp2 is output to the said one end of the current path of the switch element SW1 as the first output voltage Vo1 of the amplifier 19. The output voltage of the amplifier amp3 is output to the said other end of the current path of the switch element SW1 as the second output voltage V02 of the amplifier 19. Each of the amplifiers amp2 and amp3 has a gain −A2.

The amplifiers amp2 and amp3 are configured such that a high impedance state is set between the amplifiers amp2 and amp3 if the stop signal SS is input.

### <6. Output Operation of LVDS Driver 11>

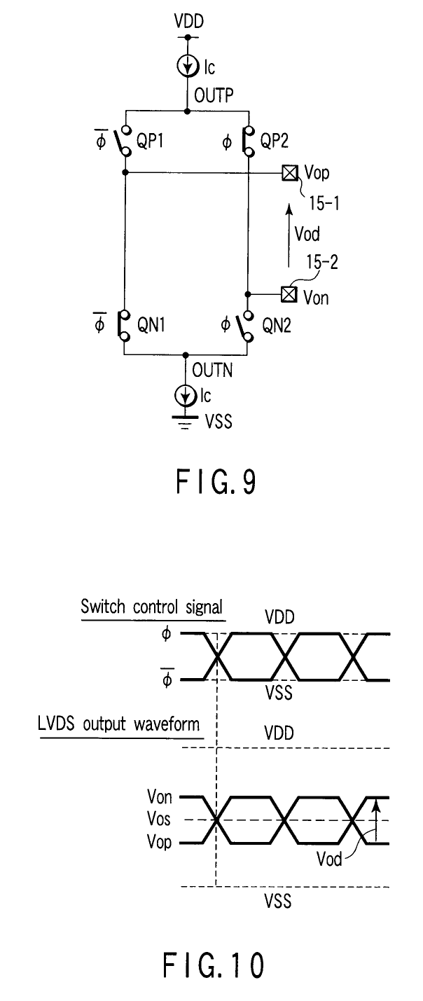

Next, the output operation of the LVDS driver 11 according to this embodiment is described with reference to FIG. 9 and FIG. 10. In FIG. 9, the MOS transistors QP1, QP2, QN1 and QN2 are schematically depicted as switches.

As shown in FIG. 9, control signals Φ and −Φ are input to the gates of the switch transistors QP1, QP2, QN1 and QN2 of the LVDS output circuit 16. The control signals Φ and −Φ have waveforms as shown in the upper part of FIG. 10.

Accordingly, the LVDS driver 11 has output waveforms (Vop, Von) as shown in the lower part of FIG. 10. As shown in FIG. 10, the LVDS driver 11 outputs small-amplitude differential output signals Vop and Von, with an offset voltage Vos being set as a reference voltage.

<7. Comparison with a Driver According a Comparative Example>

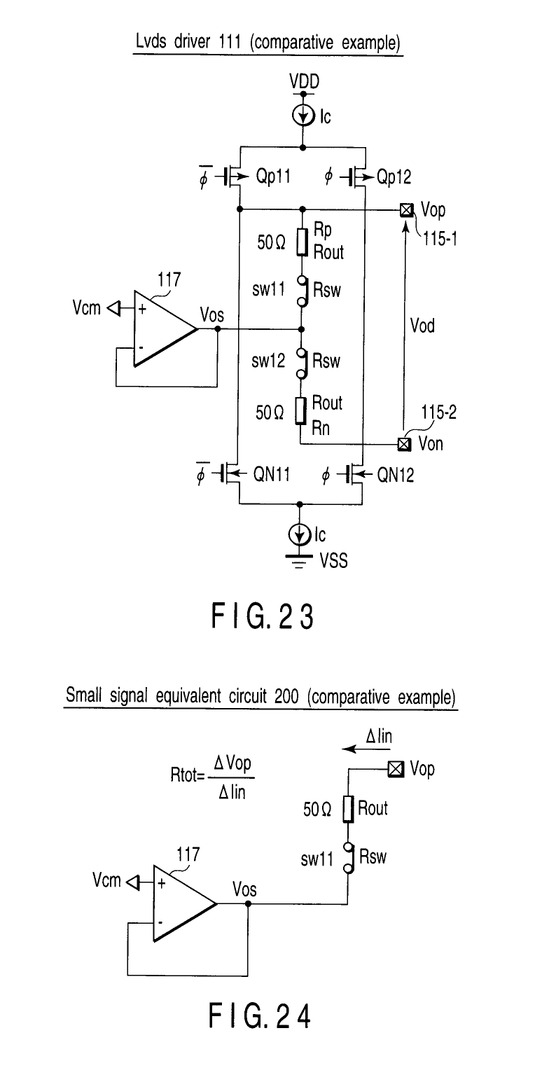

Next, referring to FIG. 23 to FIG. 28, a description is given of the comparison between the LVDS driver 11 according to the present embodiment and an LVDS driver 111 according to a comparative example.

FIG. 23 shows the LVDS driver 111 of the comparative example. As shown in FIG. 23, the LVDS driver 111 of the comparative example differs from the LVDS output circuit 11 of the present embodiment in that the LVDS driver 111 includes two switch elements SW11 and SW12 and a buffer amplifier 117 as an output circuit.

### <7-1. Comparison of Output Impedance Rtot>

To begin with, an output impedance Rtot, as viewed from the output terminal (Vop) 115-1, is found in order to examine a variation in output resistance due to the insertion of ON/OFF switches SW11 and SW12 between output resistors of the LVDS driver 111 of the comparative example shown in FIG. 23.

The output resistance of the current source circuit that is composed of transistors (MOSFETs), which operate in a saturation region, is a high resistance on the order of MΩ. Thus, the output resistance of the current source circuit is sufficiently higher than the resistance values Rout and Rsw of the output resistors Rp and Rn and is ignorable. Therefore, the output impedance, as viewed from the output terminal (Vop) 115-1, can be simplified as in an equivalent circuit 200 shown in FIG. 24. In addition, since the output impedance of the buffer amplifier 117, which generates an operation point reference voltage Vos, actually has a finite value, this impedance has to be also considered. The buffer amplifier 117 is composed of an ordinary operational amplifier.

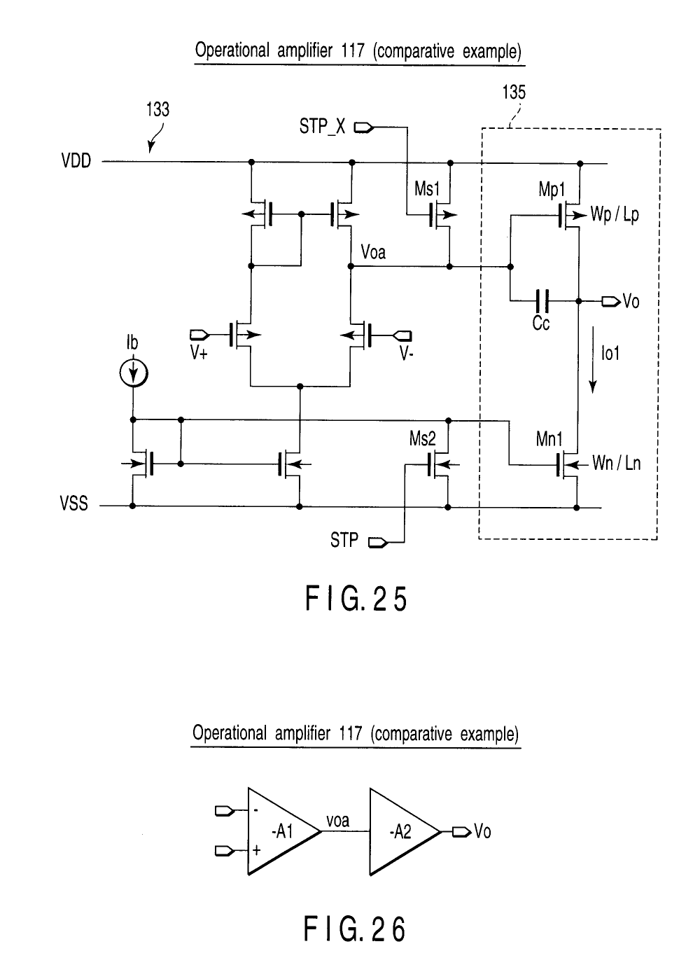

For example, FIG. 25 shows a case in which an operational amplifier circuit having an ordinary 2-stage amplifier structure is used as the buffer amplifier 117. A potential difference between input voltages V+ and V− is amplified by an input-stage amplifier and the amplified potential difference is output as an output voltage Voa. An output voltage of an output amplification stage, which receives this output voltage Voa, is a voltage V0

In the meantime, as shown in FIG. 26, the buffer amplifier 117 may be simplified as a model having a total gain of A1*A1 multiplication, that is, −A1 multiplication at the input stage and −A2 multiplication at the output stage.

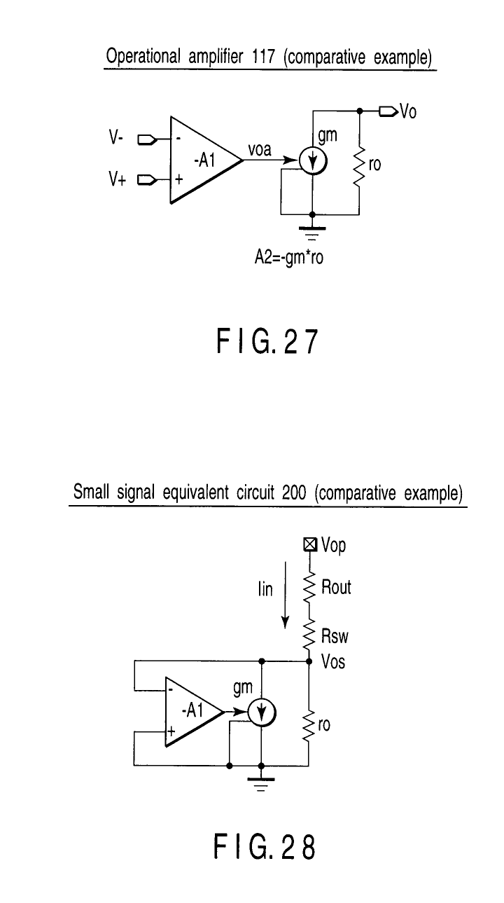

In the case of the structure of the buffer amplifier 117 shown in FIG. 25, the output amplification stage is composed of a source-grounded amplifier of transistors Mn1 and Mp1. Thus, as shown in FIG. 27, the buffer amplifier 117 can be represented by a small signal equivalent circuit diagram which shows a first-stage −A1 multiplication amplifier stage, a voltage control current source which is a model of the transistor Mp1, and an output resistor ro. The input voltage of the voltage control current source is the above-described voltage Voa, and an electric current, which is obtained by multiplying the voltage Voa by a transconductance gm, is caused to flow.

If the size of the transistor Mp1 shown in FIG. 25 is Wp/Lp (Wp: gate width, Lp: gate length) and the value of the bias current flowing in the output stage transistor is I01, the transconductance gm and output resistance ro of the small signal equivalent circuit shown in FIG. 27 are given by the following equation (3):

$${g}_{m} = {μ}_{p} {C}_{OX} \frac{{W}_{p}}{{L}_{p}} ( VDD - Voa - \vert {V}_{{T}_{p}} \vert ) = \sqrt{2 {μ}_{p} {C}_{OX} \frac{{W}_{p}}{{L}_{p}} {I}_{o 1}} \\ {r}_{o} = \frac{1}{\frac{{λ}_{p}}{2} {μ}_{p} {C}_{OX} \frac{{W}_{p}}{{L}_{p}} {( VDD - Voa - \vert {V}_{{T}_{p}} \vert )}^{2}} = \frac{1}{{λ}_{p} {I}_{o 1}} \qquad ( 3 )$$

In equation (3), λp is a channel length modulation coefficient, which is an inherent value of a transistor (MOSFET) having process dependency.

Then, since the gain −A2 of the output stage is expressed by −gm·ro, the gain At of the entire buffer amplifier 117 is expressed by the following equation (4):

A_{T}=(−A1)×(−A2)=A1×gₘrₒ (4)

Further, if the equivalent circuit 200 of the buffer amplifier shown in FIG. 24 is replaced with the model shown in FIG. 27, an equivalent circuit 200 shown in FIG. 28 is obtained. If the output impedance Rtot, as viewed from the output terminal (Vop) 115-1, is found from the equivalent circuit 200 shown in FIG. 28, the output impedance Rtot is expressed by the following equation (5):

$$\begin{matrix}{R}_{tot} = {R}_{out} + {R}_{SW} + \frac{{r}_{o}}{1 + {g}_{m} {r}_{o} {A}_{1}} \\ = {R}_{out} + {R}_{SW} + \frac{{r}_{o}}{1 + {A}_{T}}\end{matrix} \qquad ( 5 )$$

Moreover, by using the buffer amplifier in which feedback is effected, the output resistance ro of the buffer amplifier 117 is improved to the reciprocal of the loop gain (1+At). If the output resistance of the buffer amplifier 117 is Ro_buf, the output impedance Rtot is expressed by the following equation (5a):

Rₜₒₜ=Rₒᵤₜ+Rₒ_{_{—}}_{buf}+R_{sw} (5a)

The resistor Rp, Rn having the resistance value Rout is formed of, e.g. polycrystalline silicon, and is substantially free from process variations such as temperature dependency, power supply voltage dependency and a threshold voltage of the transistor (MOSFET), although there occurs a variation in absolute value due to process conditions.

On the other hand, as regards the switch elements which are transistors (MOSFET), the value of the ON resistance Rsw of the switch SW11, SW12 greatly varies due to a temperature variation, a power supply voltage variation and a threshold voltage variation, as expressed in the above equation (1).

If it is assumed that a complete differential operation is performed with the output voltages Vop and Von at the output terminals 115-1 and 115-2 of the LVDS driver 116 according to the comparative example shown in FIG. 23, the voltage value of the output voltage Vos is in a virtual grounded state. Thus, the output impedance Rtot is expressed by the following equation (5b):

Rₜₒₜ=Rₒᵤₜ+R_{SW} (5b)

Actually, however, the complete differential operation is not performed, for example, due to an in-phase component resulting from an error current of the current value Ic that is supplied to the output voltage Vop, Von, and skew of the switch control signal Φ, −Φ.

Thus, the buffer amplifier 117 is necessary in the LVDS output driver 111 of the current output type. In order to obtain a stabler operation point voltage, it is necessary to sufficiently lower the value of the output resistance Ro_buf of the buffer amplifier, as shown in equation (5b).

From the above equation (5a), in order to decrease the process variation of the output impedance Rtot of the LVDS output driver 116, the relationship of the following equation (6) needs to be satisfied:

Rₒᵤₜ>>Rₒ_{_{—}}_{buf}+R_{SW} (6)

Normally, the resistance value Rout is a small value, for example, about 50Ω. Thus, in order to meet the relationship of equation (6), if it is assumed that the ON resistance Rsw of the switch SW11, SW12 is constituted by the transistors (MOSFET), the gate width W has to be considerably increased. This leads to an increase in device area of the switch SW11, SW12. The resistance value Ro_buf increases as the frequency becomes higher, but is a small value, e.g. about several Ω, in the vicinity of DC.

As described above, in the structure in which the two output resistor ON/OFF switch elements SW11 and SW12 are provided in the LVDS output driver 111 according to the comparative example, the gate width W of the switch element SW11, SW12 needs to be considerably increased, and the circuit area increases.

Specifically, the reason for this is that in the ordinary CMOS fabrication process, in order to make the ON resistance Rsw of the switch element SW11, SW12 sufficiently lower than the resistance of the LVDS output resistor Rp, Rn (e.g. about 50Ω), the gate width W needs to be considerably increased. The increase in area of the switch element SW11, SW12, which is the transistor (MOSFET), leads to an increase in circuit area and an increase in manufacturing cost. In addition, a parasitic capacitance between the gate and drain and between the gate and source of the transistor (MOSFET) increases, and power supply noise may easily mix in.

If the added resistance value of the ON resistances Rsw and Rout is Rtot, the resistance value Rtot becomes the output resistance of the LVDS driver 111. It is thus considered that it should suffice to set the ON resistance Rout so as to obtain the output resistance Rtot=50Ω, taking the resistance value of the ON resistance Rsw into account in advance in the stage of design.

In fact, however, there is a variation of about 50% to 200% or more due to process variations of the ON resistance Rsw of the switch element SW11 and variations in operational conditions. Therefore, the ON resistance Rsw should be as small as possible, relative to the ON resistance Rout, in order to limit the variations of the output resistance value of the resistance value Rtot and differential output amplitude Vod within the ranges that are set by specifications.

As has been described above, the example of the structure of the LVDS driver 111 according to the comparative example is disadvantageous for microfabrication.

### <7-2. Detailed Comparison of Electrical Characteristics>

Next, detailed analysis and comparison of electrical characteristics are made between the LVDS driver 11 shown in FIG. 8 according to the present embodiment and the LVDS driver 111 shown in FIG. 23 according to the comparative example.

As shown in FIG. 23, in the LVDS driver 111 according to the comparative example, two switch elements (SW11, SW12) are interposed between the two output resistors Rp and Rn, and a middle node between the two switch elements (SW11, SW12) is connected to the output of the buffer amplifier 117.

On the other hand, in the LVDS driver 11 shown in FIG. 8 according to the present embodiment, only one switch element SW1 (resistance value Rsw1) for output resistor ON/OFF is interposed between the two output resistors Rp and Rn.

Both ends of the switch element SW1 are connected to output voltages vo1 and vo2 of the amplifiers amp2 and amp3 with the gain −A2, which receive the output of the amplifier amp1 having the gain −A1. The switches SW2 and SW3 having the same ON resistance value (Rsw2) are connected in series to both ends of the current path of the switch SW1.

The connection point of the switch elements SW2 and SW3 has an average voltage ((vo1+vo2)/2) between both ends of the current path of the switch element SW1. This average voltage is connected to the negative input terminal of the amplifier amp1. The positive input terminal of the amplifier amp1 is connected to the reference potential Vcm.

As has been described above, at first, the LVDS driver 11 of the present embodiment differs from the LVDS driver 111 of the comparative example in that the LVDS driver 11 requires only one switch element SW1 between the output resistors RP and RN whereas the LVDS driver 111 needs to have two transistor (MOSFET) switch elements between the output resistors Rp and Rn, which require a large area.

The switch elements SW2 and SW3, which are included in the 2-input-2-output amplifier 19 in the present embodiment, are provided only for the purpose of generating an average voltage between both ends of the current path of the switch element SW1. Thus, the resistance value Rsw2 of the switch element SW2, SW3 can be made sufficiently higher than the resistance value Rsw1 of the switch element SW1, and the occupation area of the switches SW2 and SW3 may be small.

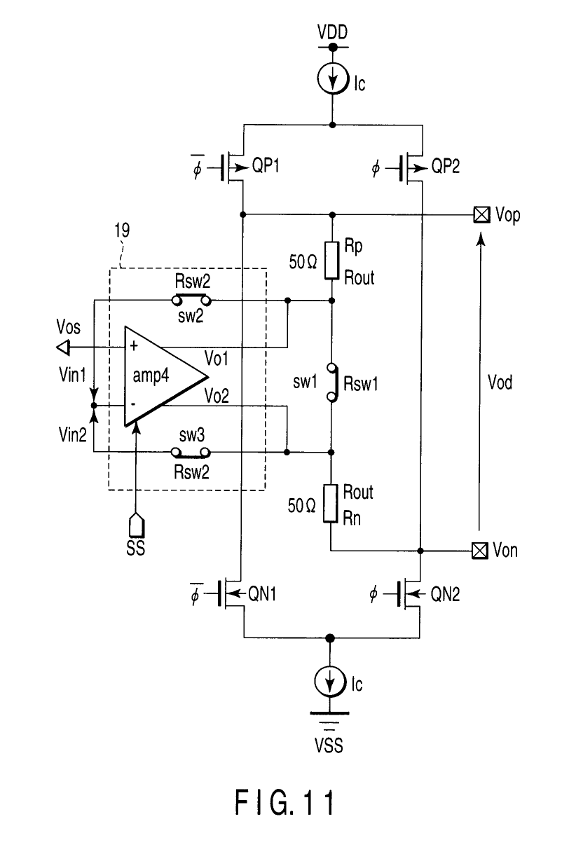

As shown in FIG. 11, a structure having a single operational amplifier may be adopted by integrating the above-described amplifiers amp1, amp2 and amp3 into an amplifier amp4. The 2-input-2-output amplifier 19, as shown in FIG. 11, similarly outputs two output voltages vo1 and vo2 from the two output terminals.

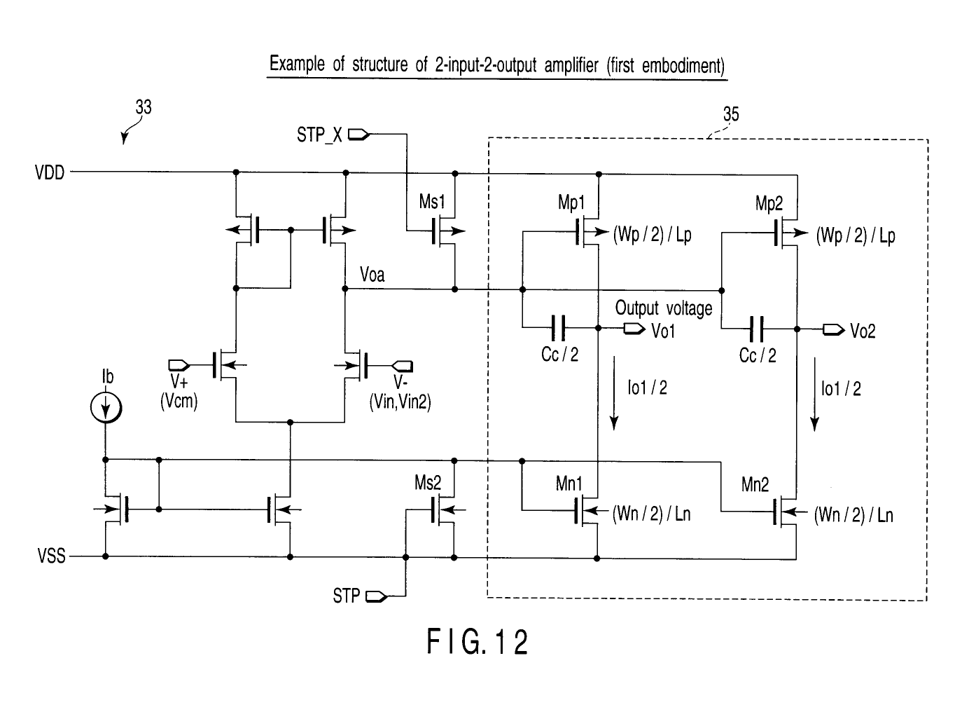

FIG. 12 shows a circuit diagram of the 2-input-2-output amplifier 19 shown in FIG. 8. As shown in FIG. 12, the 2-input-2-output amplifier 19 includes a first-stage amplifier section 33 and an output-stage amplifier section 35.

The first-stage amplifier section 33 receives input voltages V+ and V−, and produces an output voltage Voa. This first-stage amplifier section 33 is the same as a first-stage amplifier section 133 shown in FIG. 25 according to the comparative example.

The output-stage amplifier section 35 receives the output voltage Voa from the first-stage amplifier section 33, and produces two output voltages Vo1 and Vo2.

The output-stage amplifier section 35 includes transistors (MOSFETs) Mp1, Mp2, Mn1 and Mn2, and capacitors Cc.

Comparison will now be made with an output-stage amplifier section 135 of the buffer amplifier 117 according to the comparative example shown in FIG. 25. The output-stage amplifier section 35 of the present embodiment differs from the output-stage amplifier section 135 of the comparative example in that output-stage amplifier sections 135 are connected in parallel in the output-stage amplifier section 35.

The gate width of each of the transistors Mp1 and Mp2 has half the value (Wp/2). In addition, the gate width of each of the transistors Mn1 and Mn2 has half the value (Wn/2). The capacitance value (phase compensation capacitance) of each of the capacitors Cc has half the value (Cc/2).

As described above, the occupation area of the entire 2-input-2-output amplifier 19 of the present embodiment can be made substantially equal to the occupation area of the operational amplifier 117 according to the comparative example. In short, the occupation area is not increased by this structure.

When the conduction path between the output resistors RP and RN shown in FIG. 8 is set in the OFF state, the switch elements SW1 and SW2 are turned off and the output voltages vo1 and vo2 of the operational amplifiers amp2 and amp3 are set in the high impedance state. To be more specific, in order to set the output voltages vo1 and vo2 in the high impedance state, the stop signal SS is input to an STP terminal and an STP_X terminal in FIG. 12. If the control signal SS is input, a VSS voltage is applied to the STP terminal to cut off the transistor Mn2, and a VDD voltage is applied to the STP_X terminal to cut off the transistor Mp2.

Next, referring the example of the structure of the LVDS driver 11 shown in FIG. 8, the output resistance Rtot in this embodiment is found.

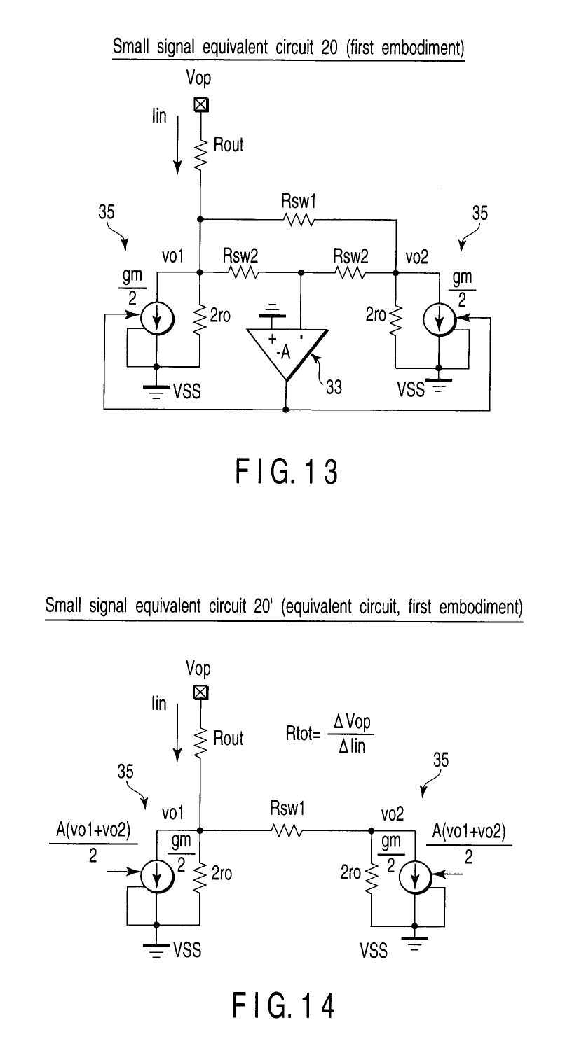

To begin with, consider a small signal equivalent circuit for calculating an impedance as viewed from Vop, as in the case where the output resistance of the LVDS driver 111 of the comparative example is calculated. Specifically, FIG. 13 shows a small signal equivalent circuit of the 2-input-2-output amplifier 19 shown in FIG. 12.

As shown in FIG. 13, the resistance values of the switch elements SW1 and SW2 are represented by Rsw1 and Rsw2, the gain of the first-stage amplifier section 33 of the 2-input-2-output amplifier 19 is represented by an amplifier −A1, and the output-stage amplifier section 35 is represented by voltage control current supply circuits (transconductance: gm/2) and an output resistor (resistance value Rout).

The gate width of each of the transistors (MOSFETs) Mp1, Mp2, Mn1 and Mn2, which constitute the output-stage amplifier section 35 of the present embodiment, is half the gate width (Wp/2, Wn/2) of each of the transistors which constitute the output-stage amplifier section 135 of the operational amplifier 117 in FIG. 25 according to the comparative example. Thus, from the above equation (3), the transconductance of the voltage control current source circuit of the output-stage amplifier section 35 of the present embodiment is gm/2. Similarly, from the equation (3), the output resistance is 2ro.

If the small signal equivalent circuit 20 shown in FIG. 13 is further simplified, an equivalent circuit shown in FIG. 14 may be considered.

As shown in FIG. 14, the input to the output-stage amplifier section 33 with the gain −A1 of the small signal equivalent circuit 20′ is considered to be an average value of the input voltages Vo1 and Vo2. Accordingly, each of the inputs to the two output-stage amplifier sections 35 is −A1(vo1+vo2)/2. In addition, since the resistance value Rsw2 is a resistance only for the purpose of generating the average voltage of the input voltages Vo1 and Vo2, it may be considered that the resistance value Rsw2 is sufficiently higher than the resistance value Rsw1, and the resistance value between the input voltages Vo1 and Vo2 may be considered to be substantially equal to the resistance value Rsw1.

Using the small signal equivalent circuit 20′ shown in FIG. 14, the output resistance Rtot of the LVDS driver 11 of the present embodiment is found. When a current Iin is let to flow in from the terminal Vop, the current Iin is expressed by the following equation (7) by using the terminal voltages Vo1 and Vo2:

$$\begin{matrix}{I}_{in} = 2 \times \frac{{g}_{m}}{2} \frac{A ( {v}_{o 1} + {v}_{o 2} )}{2} + \frac{{v}_{o 1} + {v}_{o 2}}{2 {r}_{o}} \\ = ( \frac{1 + {Ag}_{m} {r}_{o}}{{r}_{o}} ) ( \frac{{v}_{o 1} + {v}_{o 2}}{2} )\end{matrix} \qquad ( 7 )$$

In addition, there is a relationship expressed by the following equation (8):

$$\frac{{v}_{o 1 -} {v}_{o 2}}{{R}_{SW 1}} = \frac{{v}_{o 2}}{2 {r}_{o}} + \frac{{g}_{m}}{2} \frac{A ( {v}_{o 1} + {v}_{o 2} )}{2} \qquad ( 8 )$$

If the terminal voltage V02 is deleted from equations (7) and (8), the current Iin can be calculated by the following equation (9):

$${I}_{in} = \frac{1 + {Ag}_{m} {r}_{o}}{{r}_{o}} \frac{1}{2} \{ \frac{\frac{1}{2 {r}_{o}} + \frac{2}{{R}_{SW 1}}}{\frac{1}{2 {r}_{o}} + \frac{1}{{R}_{SW 1}} + \frac{{g}_{m} A}{4}} \} {v}_{oa} \qquad ( 9 )$$

Further, from the equation (9), the output resistance Rtot as viewed from the terminal Vop is expressed by the following equation (10):

$${R}_{tot} = \frac{Δ {V}_{OP}}{Δ {I}_{in}} = {R}_{out} + \frac{{r}_{o}}{1 + {Ag}_{m} {r}_{o}} + ( \frac{{R}_{SW 1}}{4} ) // ( 2 {r}_{o} ) \qquad ( 10 )$$

The second term in the equation (10) is the same value as the output impedance of the operational amplifier 117 shown in FIG. 25 according to the comparative example, and this value is Ro_buf. The third term of the equation (10) represents a parallel resistance of the resistance value Rsw/4 and resistance value 2ro. The output resistance of the operational amplifier, in which no feedback is executed, is normally several kΩ to several-ten kΩ and is high. Since the resistance value Rsw is inherently a smaller value than the resistance value Rout (e.g. about 50Ω), the parallel resistance value of the third term is substantially determined by only the resistance value Rsw. Therefore, the output resistance Rtot can be approximated by the following equation (11a):

$${R}_{tot} = {R}_{out} + {R}_{o\_buf} + \frac{{R}_{SW 1}}{4} \qquad ( 11 a )$$

If it is assumed that a complete differential operation is performed with the output voltages Vop and Von, the middle point of the resistance value Rsw1 shown in FIG. 14 is in a virtual grounded state. Accordingly, Vo1+Vo2=0 and the resistance value as viewed from the terminal voltage Vo1 becomes the parallel resistance of the resistance values 2ro and Rsw1/2. Since the ON resistance value ro is sufficiently higher than the resistance value Rsw, the equation (11a) is expressed by the following equation (11b):

$$\begin{matrix}{R}_{tot} = {R}_{out} + 2 {r}_{o} // \frac{{R}_{SW 1}}{4} \\ ≅ {R}_{out} + \frac{{R}_{SW 1}}{4}\end{matrix} \qquad ( 11 b )$$

From the above equations, the output resistance Rtot of the LVDS driver 11 shown in FIG. 11 according to the present embodiment and the output resistance Rtot of the LVDS driver 111 shown in FIG. 23 according to the comparative example are compared and expressed as follows:

Rₜₒₜ=Rₒᵤₜ+Rₒ_{_{—}}_{buf}+R_{SW} (5a)

(the output resistance value in the comparative example)

$${R}_{tot} = {R}_{out} + {R}_{o\_buf} + \frac{{R}_{SW 1}}{4} \qquad ( 11 a )$$

(the output resistance value in the present embodiment)

### <At Time of Complete Differential Operation>

Rₜₒₜ=Rₒᵤₜ+R_{SW} (5b)

(the output resistance value in the comparative example)

$${R}_{tot} = {R}_{out} + \frac{{R}_{SW 1}}{4} \qquad ( 11 b )$$

(the output resistance value in the present embodiment)

In each of the case where the complete differential operation is performed (equation (11b)) and the case where the complete differential operation is not performed (equation (11a)), the resistance value of the switch element SW1 of the LVDS driver 11 of the present embodiment can be decreased.

For example, in the case of the present embodiment, as indicated by the above equations (11a) and (11b), it is understood that the resistance value of the switch element SW1 can be reduced to ¼, compared to the comparative example. However, this is considered on the basis of the case in which the switch elements SW11 and SW12 of the driver 111 shown in FIG. 23 according to the comparative example and the switch element SW1 in FIG. 11 according to the present embodiment are composed of the MOSFET switch of the same area.

As described above, the resistance value Rsw1 of the switch element SW1, which becomes an unnecessary resistance, can be reduced. In addition, it is possible to suppress the process variation of the resistance value Rsw and the variation of Rtot due to a power supply voltage variation and an operational environment.

Furthermore, in the LVDS driver 111 according to the comparative example shown in FIG. 23, the switch element SW11 is provided on the voltage Vop side, and the switch SW12 is also provided on the voltage Von side. Since the two switch elements are provided, the occupation area is doubled, compared to the case of the present embodiment in which one switch SW1 is provided, and the manufacturing cost increases.

In the example of the structure of the LVDS driver 111 according to the comparative example, in the case where the output resistance, as viewed from the voltage Vop and voltage Von, is to be set at a high impedance, it may be considered that the two switches, namely the switches SW11 and SW12, are not necessarily needed. However, at the time of the actual operation of the LVDS driver 111 according to the comparative example, if consideration is given to the differential amplitude of the voltage Vop and voltage Von with the voltage Vos being set as the reference voltage, and to the balance in circuit configuration, it is not preferable in terms of circuit characteristics to insert the switch element only on one of the voltage Vop side and the voltage Von side. Therefore, in the example of the structure of the LVDS driver 111 according to the comparative example, the two switch elements, namely the switch SW11 and switch SW12, are necessary and indispensable.

### <8. Advantageous Effects of the Driver According to the Present Embodiment>

According to the driver 11 of the present embodiment, at least the following advantageous effects (1) to (4) can be obtained.

(1) Since the occupation area of the switch element SW1 of the output section (2-input-2-output amplifier 19) can be reduced, lower cost can advantageously be achieved.

As described above, the LVDS driver 11 according to the present embodiment includes the single switch element SW1, and the conduction path between the output terminals 15-1 and 15-2 (i.e. between the voltage Vop and voltage Von) can be ON/OFF controlled by the switch SW1 alone.

Since the occupation area of the 2-input-2-output amplifier 19 can be reduced, lower cost can advantageously be achieved. For example, since the LVDS driver 111 according to the comparative example is configured to require the two switch elements SW11 and SW12, the LVDS driver 111 formally has double the occupation area for the switch.

Moreover, according to the present embodiment, the occupation area of the switch element SW1 itself can be reduced.

For example, in the case where the output resistors Rp and Rn of the LVDS driver 11 of the present embodiment are ON/OFF controlled by the switch element, consideration is given to the condition that the ratio of the ON resistance of the MOSFET switch, relative to the Rout (e.g. about 50Ω), is constant. Under this condition, the device area of the switch element SW1 (MOSFET) of the present embodiment can be reduced to ⅛, compared to the switch elements SW11 and SW12 in the comparative example.

The resistance values Rsw1 and Rsw2 of the switch elements SW2 and SW3 of the 2-input-2-output amplifier 19 may be sufficiently higher than the output resistance Rout. Therefore, these resistance values are ignorable in relation to the device area of the switch element SW1.

(2) The ON resistance of the switch element SW1 can be reduced.

In each of the case where the complete differential operation is performed (equation (11b)) and the case where the complete differential operation is not performed (equation (11a)), the ON resistance value of the switch element SW1 of the LVDS driver 11 of the present embodiment can be decreased.

For example, in the case of the present embodiment, as indicated by the above equations (11a) and (11b), the resistance value of the switch element SW1 can be reduced to ¼, compared to the comparative example.

However, this is the example in the case where the switch elements SW11 and SW12 of the driver 111 shown in FIG. 23 according to the comparative example and the switch element SW1 in FIG. 11 according to the present embodiment are composed of the MOSFET switch of the same area.

(3) Mixing of power supply noise can be prevented.

As described in the above (1), according to the structure of the present embodiment, the occupation area of the switch element SW1 can be decreased.

It is thus possible to prevent an increase in parasitic capacitance between the gate and drain and between the gate and source, which occurs due to an increase in occupation area of the switch element SW1. Therefore, mixing of power supply noise can be prevented.

(4) The manufacturing cost can advantageously be reduced.

For example, in the case where the ON resistance of the switch element, which has a sufficiently smaller resistance value relative to the normal Rout (e.g. about 50Ω), is constituted, a considerably large area is required and the manufacturing cost increases.

However, as described in the above (1) and (2), according to the structure of the present embodiment, the occupation area and the ON resistance of the switch element SW1 can be reduced. Thus, a sufficiently low ON resistance of the switch element SW1, relative to the normal Rout (e.g. about 50Ω), can be realized, and the occupation area can be reduced. Therefore, the manufacturing cost can advantageously be reduced.

### Second Embodiment

### An Example Including an Average Voltage Generating Circuit and a 2-Output Amplifier

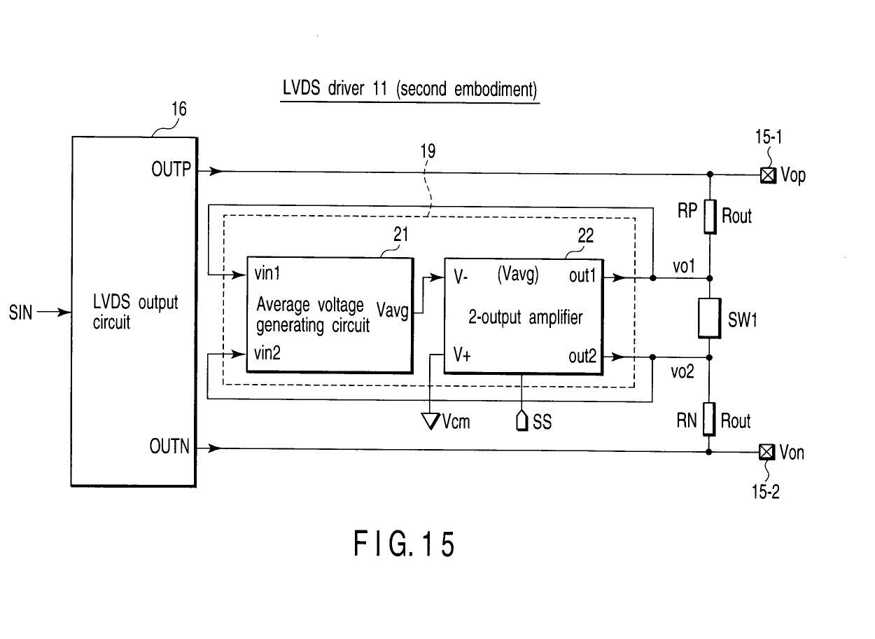

Next, a driver according to a second embodiment of the present invention is described with reference to FIG. 15 to FIG. 20. This embodiment relates to an example in which the above-described 2-input-2-output amplifier 19 includes an average voltage generating circuit 21 and a 2-output amplifier 22. In the description below, a detailed description of the parts, which are common to those in the first embodiment, is omitted.

At first, the second embodiment differs from the first embodiment in that the 2-input-2-output amplifier 19, as shown in FIG. 15, includes the average voltage generating circuit 21 and the 2-output amplifier 22.

The average voltage generating circuit 21 is configured to receive, as first and second input voltages, the first and second input voltages (Vin1, Vin2) corresponding to voltages at both ends of the output resistor switch element SW1, and to output, as an output voltage, an average voltage (Vavg) of the first and second input voltages (Vin1, Vin2) to a negative (−) input terminal (V−) of the 2-output amplifier 22.

The 2-output amplifier 22 is configured to output once gain, voltages, which are obtained by amplifying a voltage difference between the average voltage (Vavg) that is input to the negative (−) input terminal (V−) and a reference voltage (Vcm) that is input to a positive (+) input terminal (V+), to both ends of the output resistor switch element SW1 as first and second output voltages (out1, out2). In addition, the 2-output amplifier 22 is configured such that if the stop signal SS is input to the 2-output amplifier 22, a high impedance state is set between both ends of the output resistor switch element SW1.

The output resistance Rtot, as viewed from the output terminal 15-1 side (Vop side), in the embodiment that is composed by combining the 2-output amplifier 22 and the arbitrary average voltage generating circuit 21, is expressed by the following equation (12):

$${R}_{tot} = {R}_{out} + \frac{1}{2 {G}_{m}} + \frac{{R}_{SW 1}}{4} \qquad ( 12 )$$

As expressed in the above equation (12), like the first embodiment, the resistance value Rsw1 of the output resistor switch element can be reduced to ¼.

### <Average Voltage Generating Circuit 21-1>

Examples of the structure of the average voltage generating circuit 21 are as follows.

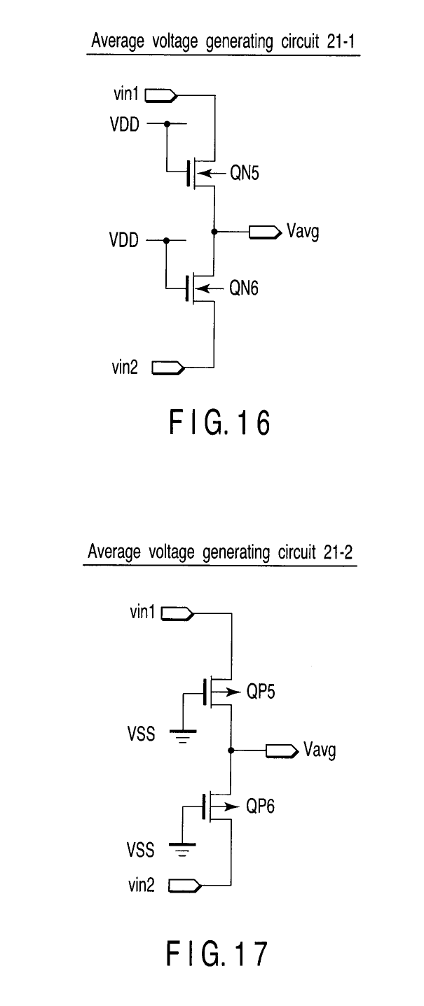

An average voltage generating circuit 21-1 shown in FIG. 16 is composed of NMOS transistors QN5 and QN6 which have current paths connected in series between the inputs (Vin1, Vin2).

One end of the current path of the NMOS transistor QN5 is connected to the input (Vin1), the other end of the current path of the NMOS transistor QN5 is connected to the output (Vavg), and the gate of the NMOS transistor QN5 is connected to an internal power supply VDD.

One end of the current path of the NMOS transistor QN6 is connected to the input (Vin2), the other end of the current path of the NMOS transistor QN6 is connected to the output (Vavg), and the gate of the NMOS transistor QN6 is connected to an internal power supply VDD.

### <Average Voltage Generating Circuit 21-2>

An average voltage generating circuit 21-2 shown in FIG. 17 is composed of PMOS transistors QP5 and QP6 which have current paths connected in series between the inputs (Vin1, Vin2).

One end of the current path of the PMOS transistor QP5 is connected to the input (Vin1), the other end of the current path of the PMOS transistor QP5 is connected to the output (Vavg), and the gate of the PMOS transistor QP5 is connected to a ground power supply VSS.

One end of the current path of the PMOS transistor QP6 is connected to the input (Vin2), the other end of the current path of the PMOS transistor QP6 is connected to the output (Vavg), and the gate of the PMOS transistor QP6 is connected to a ground power supply VSS.

### <Average Voltage Generating Circuit 21-3>

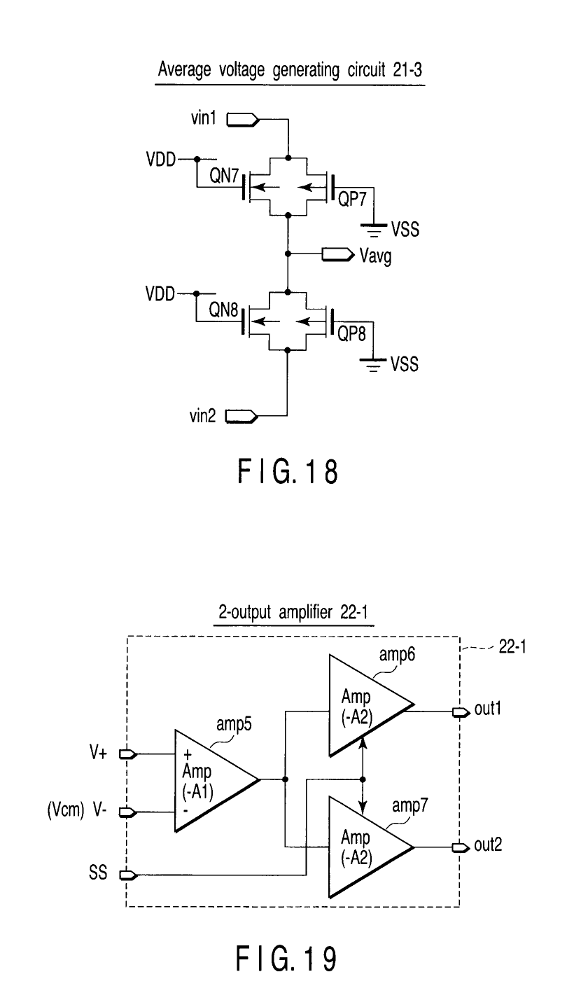

An average voltage generating circuit 21-3 shown in FIG. 18 is composed of MOS transistors QN7, QN8, QP7 and QP8 which are CMOS-connected between the inputs (Vin1, Vin2).

One end of the current path of the MOS transistor QN7 is connected to the input (Vin1), the other end of the current path of the MOS transistor QN7 is connected to the output (Vavg), and the gate of the PMOS transistor QN7 is connected to the internal power supply VDD. One end of the current path of the MOS transistor QP7 is connected to the input (Vin1), the other end of the current path of the MOS transistor QP7 is connected to the output (Vavg), and the gate of the MOS transistor QP7 is connected to the ground power supply VSS.

One end of the current path of the MOS transistor QN8 is connected to the input (Vin2), the other end of the current path of the MOS transistor QN8 is connected to the output (Vavg), and the gate of the MOS transistor QN8 is connected to the internal power supply VDD. One end of the current path of the MOS transistor QP8 is connected to the input (Vin2), the other end of the current path of the MOS transistor QP8 is connected to the output (Vavg), and the gate of the MOS transistor QP8 is connected to the ground power supply VSS.

This average voltage generating circuit 21-3 is composed of the MOS transistors QN7, QN8, QP7 and QP8 which are CMOS-connected between the inputs (Vin1, Vin2). Thus, even if the output voltage Vavg increases, the increase in ON resistance can advantageously be suppressed.

On the other hand, the average voltage generating circuits 21-1 and 21-2 are advantageous for microfabrication since the number of MOS transistors, which are structural components, can be reduced.

### <2-Output Amplifier 22-1>

Examples of the structure of the 2-output amplifier 22 are as follows.

A 2-output amplifier 22-1 shown in FIG. 19 comprises amplifiers amp5, amp6 and amp7.

The amplifier amp5 receives an input voltage V+at an input (+) thereof and receives an input voltage V− at an input (−) thereof, and outputs an output voltage, which is produced by amplifying a voltage difference between the input voltage V+ and the input voltage V−, to the inputs of the amplifiers amp6 and amp7.

The amplifiers amp6 and amp7 amplify the input voltage from the amplifier amp5, and output the amplified voltages to the output terminals out1 and out2 as output voltages. When the stop signal SS is input to the amplifiers amp6 and amp7, the amplifiers amp6 and amp7 are set in a high impedance state. Thereby, a high impedance state is set between the output terminals out1 and out2.

### <2-Output Amplifier 22-2>

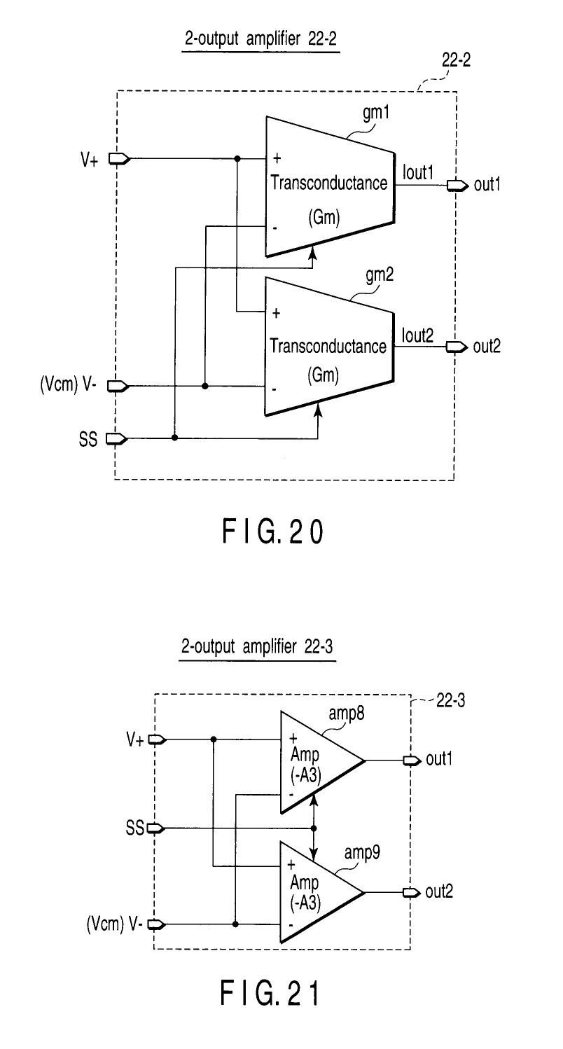

A 2-output amplifier 22-2 shown in FIG. 20 is configured to include transconductances gm1 and gm2 each having a transconductance Gm, and to output currents Iout1 and Iout2 to the output terminals out1 and out2.

The transconductance gm1 receives an input voltage V+at an input (+) thereof and receives an input voltage V− at an input (−) thereof, and outputs an output voltage Iout1, which is produced by amplifying a voltage difference between the input voltage V+ and the input voltage V−, to the output terminal out1.

The transconductance gm2 receives an input voltage V+at an input (+) thereof and receives an input voltage V− at an input (−) thereof, and outputs an output voltage Iout2, which is produced by amplifying a voltage difference between the input voltage V+ and the input voltage V−, to the output terminal out2.

When the stop signal SS is input to the transconductances gm1 and gm2, a high impedance state is set between the transconductances gm1 and gm2. Thereby, a high impedance state is set between the output terminals out1 and out2.

With the above-described structure, the 2-output amplifier 22-2 can output, from the output terminals out1 and out2, the current values Iout1 and Iout2 which are produced by multiplying the voltage difference between the positive input terminal (V+ side) and the negative input terminal (V− side) by the transconductance Gm. For example, in the case where the voltage V− of the negative input terminal is higher than the voltage V+ of the positive input terminal, the 2-output amplifier 22-2 operates so as to take in the current from the output terminal out2. Ideally, it is preferable that the output terminals out1 and out2 of the 2-output amplifier 22-2 have infinite impedance.

### <2-Output Amplifier 22-3>

A 2-output amplifier 22-3 shown in FIG. 21 is configured to include amplifiers amp8 and amp9 each having a gain A3.

The amplifier amp8 receives an input voltage V+at an input (+) thereof and receives an input voltage V− at an input (−) thereof, and outputs an output voltage, which is produced by amplifying a voltage difference between the input voltage V+ and the input voltage V−, to the output terminal out1.

The amplifier amp9 receives an input voltage V+at an input (+) thereof and receives an input voltage V− at an input (−) thereof, and outputs an output voltage, which is produced by amplifying a voltage difference between the input voltage V+ and the input voltage V−, to the output terminal out2. When the control signal SS is input to the amplifiers amp8 and amp9, the amplifiers amp8 and amp9 are set in a high impedance state. Thereby, a high impedance state is set between the output terminals out1 and out2.

As has been described above, according to the driver 11 of the present embodiment, at least the same advantageous effects as the above-described (1) to (4) can be obtained. The structure of this embodiment is applicable where necessary.

### Third Embodiment

### Another Example of the Structure of the 2-Input-2-Output Amplifier

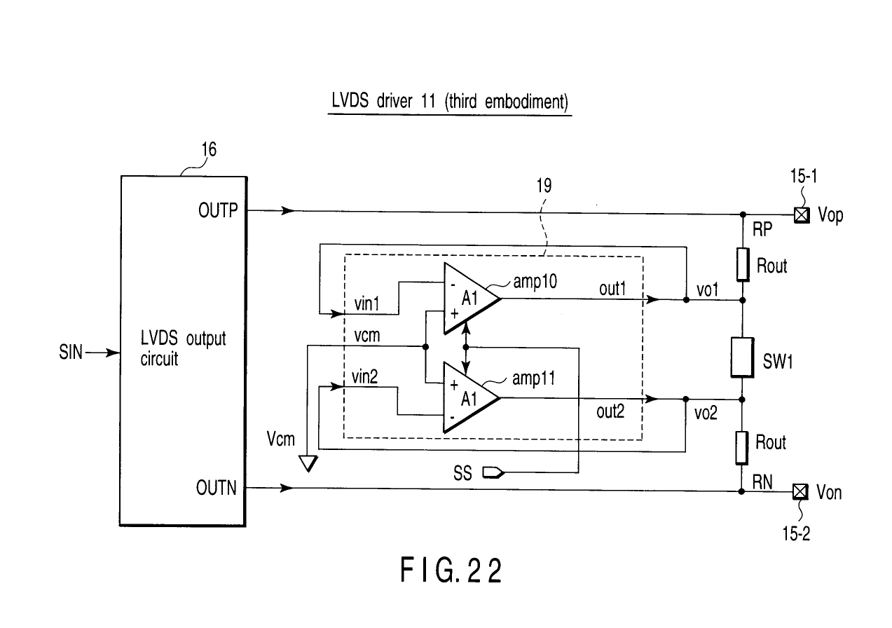

Next, a driver according to a third embodiment of the present embodiment is described with reference to FIG. 22. This embodiment relates to another example of the structure of the 2-input-2-output amplifier 19, wherein the above-described average voltage generating circuit 21 is not provided. In the description below, a detailed description of the parts common to those in the first embodiment is omitted.

As shown in FIG. 22, the 2-input-2-output amplifier 19 according to the third embodiment differs from the second embodiment in that the average voltage generating circuit 21 in the second embodiment is not provided.

The 2-input-2-output amplifier 19 according to the third embodiment includes amplifiers amp10 and amp11 each having a gain A1.

Positive input terminals (+) of the amplifiers amp10 and amp11 are connected to the reference voltage Vcm. The amplifier amp10 receives an input voltage Vin1 at a negative input terminal (−) thereof, and outputs an output voltage Vo1, which is produced by amplifying a difference voltage between the input voltage Vin1 and the reference voltage Vcm, to the output terminal out1 as an output voltage Vo1.

The amplifier amp11 receives an input voltage Vin2 at a negative input terminal (−) thereof, and outputs an output voltage Vo2, which is produced by amplifying a difference voltage between the input voltage Vin2 and the reference voltage Vcm, to the output terminal out2 as an output voltage Vo2.

In the driver 11 of the present embodiment, the occupation area does not increase, compared to the driver 111 of the comparative example. For example, consideration is now given to the case where the amplifier amp10, amp11 is composed of MOSFETs each having a gate width (W) which is scaled to about ½ of the gate width (W) of each of the MOSFETs that constitute the operational amplifier 117 according to the comparative example. Even in this case, the occupation area of the 2-input-2-output amplifier 19 of this embodiment is equal to the occupation area of the buffer amplifier 117 of the comparative example. Thus, even if the driver 11 of this embodiment is applied, the occupation area does not increase.

Nevertheless, the output resistance of each one of the amplifiers amp10 and amp11 is doubled (2Ro_buf), compared to the resistance value Ro_buf of the buffer amplifier 117 of the comparative example.

However, the output resistance Rtot, as viewed from the output terminal 15-1 side (voltage Vop side), is expressed by the following equation (13):

$$\begin{matrix}{R}_{tot} = {R}_{out} + \frac{2 {r}_{o}}{1 + {g}_{m} {r}_{o} {A}_{1}} ( \frac{2 {r}_{o}}{1 + {g}_{m} {r}_{o} {A}_{1}} + {R}_{SW 1} ) \\ = {R}_{out} + 2 {R}_{o\_buf} // ( 2 {R}_{o\_buf} + {R}_{SW 1} )\end{matrix} \qquad ( 13 )$$

As expressed in the above equation (13), since the output resistance Rtot is at least Rtot<Rout+Ro_buf+Rsw1/2, the output resistance Rtot can be made less than the output resistance of the driver circuit 111 of the comparative example.

In addition, the output resistance is also Rtot<Rout+Ro_buf. Thus, in the case where the resistance value Ro_buf is sufficiently lower than the ON resistance Rsw1, the output resistance Rtot can advantageously be determined substantially by Ro_buf alone, even if the resistance value of the ON resistance Rsw1, which increases in terms of area, is increased.

According to the driver 11 of the present embodiment, at least the same advantageous effects as the above (1) to (4) can be obtained.

Furthermore, in the structure of this embodiment, the output resistance is also Rtot<Rout+Ro_buf. Thus, in the case where the resistance value Ro_buf is sufficiently lower than the ON resistance Rsw1, the output resistance Rtot can advantageously be determined substantially by Ro_buf alone, even if the resistance value of the ON resistance Rsw1, which increases in terms of area, is increased.

### Comparative Example

### An Example in which the LVDS Output Circuit Includes Two Switch Elements

Next, in order to compare the above-described embodiments, the driver according to the comparative example will be described with reference to FIG. 23 to FIG. 28. The comparative example relates to an example in which the LVDS output circuit includes two switch elements. In the description below, a detailed description of the parts common to those in the first to third embodiments is omitted.

FIG. 23 shows the LVDS driver 111 according to the comparative example. As shown in FIG. 23, the LVDS driver 111 according to the comparative example differs from the LVDS output circuits 11 according to the first to third embodiments in that the LVDS driver 111 includes two switch elements SW11 and SW12, and includes a buffer amplifier 117 as an output circuit.

FIG. 24 is a simplified diagram showing an equivalent circuit 200 in order to explain the output impedance as viewed from the output terminal (Vop) 115-1.

FIG. 25 shows the case in which an operational amplifier circuit of an ordinary 2-stage amplifier structure is applied to the buffer amplifier 117.

FIG. 26 shows a buffer amplifier 117 as a simplified model having a total gain of A1*A2 multiplication, that is, −A1 multiplication at the input stage and −A2 multiplication at the output stage.

FIG. 27 is a small signal equivalent circuit diagram of an operational amplifier 117, in which a first-stage −A1 multiplication amplifier and a transistor Mp1 are represented by a modeled voltage control current source and an output resistor ro.

FIG. 28 is a small signal equivalent circuit diagram in a case where the buffer amplifier shown in FIG. 24 is replaced with a model as shown in FIG. 27.

With the structure of the LVDS driver according to the comparative example, the circuit area increases and this structure is disadvantageous for microfabrication.

The reason for this is as follows. In a case where a MOS transistor (MOSFET), which is fabricated by an ordinary CMOS fabrication process, is used as the above-described switch element SW11, SW12, it is necessary to make the ON resistance (Rsw) of the switch element SW11, SW12 (MOSFET) sufficiently lower than the output resistance (e.g. about 50Ω) of the LVDS driver. As a result, the gate width (W) of the switch element SW11, SW12 (MOSFET) considerably increases, and the area of occupation of the switch element SW11, SW12 greatly increases. The great increase in occupation area of the switch element SW11, SW12 leads to an increase in area of the entirety of the driver 111, and this is disadvantageous in terms of manufacturing cost.

In addition, with the great increase in occupation area of the switch element SW11, SW12, a parasitic capacitance between the gate and drain of the switch and a parasitic capacitance between the gate and source of the switch also increase, and power supply noise may easily be mixed in.

If the added resistance value of the ON resistances Rsw and Rout is Rtot, the resistance value Rtot becomes the output resistance of the LVDS driver 111 according to the comparative example. It is thus considered that it should suffice to set the ON resistance Rout so as to obtain the output resistance Rtot=50Ω, taking the resistance value of the ON resistance Rsw into account in advance in the stage of design.

However, there is a variation of about 50% to 200% or more due to process variations of the ON resistance Rsw of the switch element SW11, SW12 and variations in operational conditions. Therefore, the ON resistance Rsw should be as small as possible, relative to the ON resistance Rout, in order to limit the variations of the output resistance value of the resistance Rtot and the differential output amplitude Vod within the ranges that are set by specifications.

Taking the above into account, with the structure of the LVDS driver 111 having the ON/OFF switch elements SW11 and SW11 according to the comparative example, the occupation area increases and this structure is disadvantageous for microfabrication.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A driver comprising:
an output circuit which converts an input signal to a predetermined output waveform and outputs the predetermined waveform to first and second output terminals;
a first output resistor having one end connected to the first output terminal;
a second output resistor having one end connected to the second output terminal;
an output resistor switch element having one end connected to the other end of the first output resistor, and having the other end connected to the other end of the second output resistor; and
a 2-input-2-output amplifier which receives first and second input voltages corresponding to voltages at both ends of the output resistor switch element, and outputs voltages, which are produced by amplifying voltage differences between a reference voltage and the first and second input voltages, once again to both ends of the output resistor switch element as first and second output voltages, a high impedance state being set between both ends of the output resistor switch element when a stop signal is input to the 2-input-2-output amplifier.

2. The driver according to claim 1, wherein the output circuit comprises:
a first current source having an input connected to a first reference power supply;
a second current source having an input connected to a second reference power supply;
a first transistor of a first conductivity type, which has a current path with one end connected to the first output terminal and the other end connected to an output of the first current source;
a second transistor of the first conductivity type, which has a current path with one end connected to the second output terminal and the other end connected to the output of the first current source;
a first transistor of a second conductivity type, which has a current path with one end connected to the first output terminal and the other end connected to an output of the second current source; and
a second transistor of the second conductivity type, which has a current path with one end connected to the second output terminal and the other end connected to the output of the second current source.

3. The driver according to claim 1, wherein the output resistor switch element is a transistor of a first conductivity type or a second conductivity type, which has a current path with one end and the other end connected to said other ends of the first and second output resistors, or is a CMOS switch which has a current path with one end and the other end connected to said other ends of the first and second output resistors.

4. The driver according to claim 1, wherein the 2-input-2-output amplifier comprises:
a first switch element which has a current path with one end connected to said other end of the first output resistor, and with the other end connected to a first input of the 2-input-2-output amplifier;
a second switch element which has a current path with one end connected to said other end of the second output resistor, and with the other end connected to a second input of the 2-input-2-output amplifier;
a first amplifier which has a first input terminal to which the reference voltage is input, and a second input terminal which is connected to the first input and the second input;
a second amplifier which has an input connected to an output of the first amplifier, and an output connected to said one end of the current path of the first switch element; and
a third amplifier which has an input connected to the output of the first amplifier, and an output connected to said one end of the current path of the second switch element.

5. The driver according to claim 1, wherein the 2-input-2-output amplifier comprises:
an average voltage generating circuit which receives, as first and second input voltages, the first and second input voltages corresponding to voltages at both ends of the output resistor switch element, and outputs an average voltage of the first and second input voltages as an output voltage; and
a 2-output amplifier which is configured to have a first input terminal to which an output of the average voltage generating circuit is input, and to output voltages, which are produced by amplifying a voltage difference between the average voltage that is input to the first input terminal and the reference voltage that is input to a second input terminal of the 2-output amplifier, once again to said both ends of the output resistor switch element as first and second output voltages, a high impedance state being set between both ends of the output resistor switch element when the stop signal is input to the 2-output amplifier.

6. The driver according to claim 5, wherein the average voltage generating circuit includes first and second transistors which have current paths connected in series between the first and second input voltages, a control electrode of each of the first and second transistors being connected to a reference power supply.

7. The driver according to claim 5, wherein the 2-output amplifier comprises:
a first amplifier having a first input to which the output voltage of the average voltage generating circuit is input, and a second input to which the reference voltage is input, the first amplifier outputting an output voltage which is produced by amplifying a difference between the output voltage of the average voltage generating circuit and the reference voltage;
a second amplifier which amplifies the output voltage of the first amplifier and outputs the amplified voltage as an output voltage to the first output terminal; and
a third amplifier which amplifies the output voltage of the first amplifier and outputs the amplified voltage as an output voltage to the second output terminal, a high impedance state being set between the output terminals when the stop signal is input to the third amplifier.

8. The driver according to claim 5, wherein the 2-output amplifier comprises:
a first transconductance having a first input to which the output voltage of the average voltage generating circuit is input, a second input to which the reference voltage is input, and an output which is electrically connected to said other end of the first output resistor; and
a second transconductance having a first input to which the output voltage of the average voltage generating circuit is input, a second input which is connected to the second input of the first transconductance, and an output which is electrically connected to said other end of the second output resistor.

9. The driver according to claim 1, wherein the 2-input-2-output amplifier comprises:
a first amplifier having a first input terminal to which the reference voltage is input, and a second input terminal to which the first input voltage is input, the first amplifier outputting an output voltage, which is produced by amplifying a difference between the first input voltage and the reference voltage, to the first output terminal; and
a second amplifier having a first input terminal to which the reference voltage is input, and a second input terminal to which the second input voltage is input, the second amplifier outputting an output voltage, which is produced by amplifying a difference between the second input voltage and the reference voltage, to the second output terminal.

10. A driver/receiver system comprising:
a driver, the driver including: an output circuit which converts an input signal to a predetermined output waveform and outputs the predetermined waveform to first and second output terminals; a first output resistor having one end connected to the first output terminal; a second output resistor having one end connected to the second output terminal; an output resistor switch element having one end connected to the other end of the first output resistor, and having the other end connected to the other end of the second output resistor; and a 2-input-2-output amplifier which receives first and second input voltages corresponding to voltages at both ends of the output resistor switch element, and outputs voltages, which are produced by amplifying voltage differences between a reference voltage and the first and second input voltages, once again to both ends of the output resistor switch element as first and second output voltages, a high impedance state being set between both ends of the output resistor switch element when a stop signal is input to the 2-input-2-output amplifier; and
a receiver which receives output signals of the driver, which are output from the first and second output terminals.

11. The system according to claim 10, further comprising a terminal end resistor which has one end and the other end connected between the first and second output terminals.

12. The system according to claim 10, wherein the output circuit comprises:
a first current source having an input connected to a first reference power supply;
a second current source having an input connected to a second reference power supply;
a first transistor of a first conductivity type, which has a current path with one end connected to the first output terminal and the other end connected to an output of the first current source;
a second transistor of the first conductivity type, which has a current path with one end connected to the second output terminal and the other end connected to the output of the first current source;
a first transistor of a second conductivity type, which has a current path with one end connected to the first output terminal and the other end connected to an output of the second current source; and
a second transistor of the second conductivity type, which has a current path with one end connected to the second output terminal and the other end connected to the output of the second current source.

13. The system according to claim 10, wherein the output resistor switch element is a transistor of a first conductivity type or a second conductivity type, which has a current path with one end and the other end connected to said other ends of the first and second output resistors, or is a CMOS switch which has a current path with one end and the other end connected to said other ends of the first and second output resistors.

14. The system according to claim 10, wherein the 2-input-2-output amplifier comprises:
a first switch element which has a current path with one end connected to said other end of the first output resistor, and with the other end connected to a first input of the 2-input-2-output amplifier;
a second switch element which has a current path with one end connected to said other end of the second output resistor, and with the other end connected to a second input of the 2-input-2-output amplifier;
a first amplifier which has a first input terminal to which the reference voltage is input, and a second input terminal which is connected to the first input and the second input;
a second amplifier which has an input connected to an output of the first amplifier, and an output connected to said one end of the current path of the first switch element; and
a third amplifier which has an input connected to the output of the first amplifier, and an output connected to said one end of the current path of the second switch element.

15. The system according to claim 10, wherein the 2-input-2-output amplifier comprises:
an average voltage generating circuit which receives, as first and second input voltages, the first and second input voltages corresponding to voltages at both ends of the output resistor switch element, and outputs an average voltage of the first and second input voltages as an output voltage; and
a 2-output amplifier which is configured to have a first input terminal to which an output of the average voltage generating circuit is input, and to output voltages, which are produced by amplifying a voltage difference between the average voltage that is input to the first input terminal and the reference voltage that is input to a second input terminal of the 2-output amplifier, once again to said both ends of the output resistor switch element as first and second output voltages, a high impedance state being set between both ends of the output resistor switch element when the stop signal is input to the 2-output amplifier.

16. The system according to claim 15, wherein the average voltage generating circuit includes first and second transistors which have current paths connected in series between the first and second input voltages, a control electrode of each of the first and second transistors being connected to a reference power supply.

17. The system according to claim 15, wherein the 2-output amplifier comprises:
a first amplifier having a first input to which the output voltage of the average voltage generating circuit is input, and a second input to which the reference voltage is input, the first amplifier outputting an output voltage which is produced by amplifying a difference between the output voltage of the average voltage generating circuit and the reference voltage;
a second amplifier which amplifies the output voltage of the first amplifier and outputs the amplified voltage as an output voltage to the first output terminal; and
a third amplifier which amplifies the output voltage of the first amplifier and outputs the amplified voltage as an output voltage to the second output terminal, a high impedance state being set between the output terminals when the stop signal is input to the third amplifier.

18. The system according to claim 15, wherein the 2-output amplifier comprises:
a first transconductance having a first input to which the output voltage of the average voltage generating circuit is input, a second input to which the reference voltage is input, and an output which is electrically connected to said other end of the first output resistor; and
a second transconductance having a first input to which the output voltage of the average voltage generating circuit is input, a second input which is connected to the second input of the first transconductance, and an output which is electrically connected to said other end of the second output resistor.

19. The system according to claim 10, wherein the 2-input-2-output amplifier comprises:
a first amplifier having a first input terminal to which the reference voltage is input, and a second input terminal to which the first input voltage is input, the first amplifier outputting an output voltage, which is produced by amplifying a difference between the first input voltage and the reference voltage, to the first output terminal; and
a second amplifier having a first input terminal to which the reference voltage is input, and a second input terminal to which the second input voltage is input, the second amplifier outputting an output voltage, which is produced by amplifying a difference between the second input voltage and the reference voltage, to the second output terminal.

20. The system according to claim 10, further comprising:
a first transmission line which is connected between the first output terminal and the receiver; and
a second transmission line which is connected between the second output terminal and the receiver.
